(19) United States
(12) Patent Application Publication
(10) Pub. No.: US 2010/0196831 A1
(43) Pub. Date: Aug. 5, 2010

(54) EXPOSURE APPARATUS AND DEVICE MANUFACTURING METHOD

(75) Inventor: Osamu Tsunoda, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/534,312

(22) Filed: Aug. 3, 2009

(30) Foreign Application Priority Data
Aug. 12, 2008 (JP) 2008-208253

(51) Int. Cl. G03F 7/20; G05B 19/00

(52) U.S. Cl. 430/325; 340/5.81; 700/90

(57) ABSTRACT

An exposure apparatus includes a communication device configured to communicate with a host computer; an input-output device for an operator to execute a manual operation of the apparatus; a storage device; and a processor. The apparatus exposes a substrate to radiant energy in accordance with an on-line operation from the host computer and an operator operation from the input-output device. The storage device is configured to store first information indicating a manual operation that can be executed by each operator and second information indicating an online operation of which execution concurrent with each manual operation is inhibited. The processor is configured to authenticate an operator and permit execution of an online operation from the host computer based on the first information and the second information stored in the storage device and information of the authenticated operator.

### BACKGROUND OF THE INVENTION

1. Field of the Invention

The present invention relates to an exposure apparatus used for manufacturing a device, such as a semiconductor integrated circuit device or a liquid crystal display device.

2. Description of the Related Art

During automatic online control of exposure apparatuses through online operations from host computers, operators can manually operates the exposure apparatuses because of occurrences of problems or maintenance operations. Such problems in exposure apparatuses can be caused by executing online operations from host computers concurrently with manual operations by operators, which are associated with the online operations from the host computers.

In technologies disclosed in Japanese Patent Laid-Open No. 10-172903 and Japanese Patent Laid-Open No. 11-054429, an online-operation inhibited state is set to prevent concurrent execution of an online operation from a host computer and a manual operation by an operator in order to avoid such a problem.

With the above technologies, when an operator manually operates an exposure apparatus during online control through an online operation from a host computer, it is necessary to switch to the online-operation inhibited state to execute the manual operation by the operator. In the online-operation inhibited state, all the online operations from the host computer are inhibited. Accordingly, even when the operator executes a manual operation that is not associated with the online operations from the host computer, it is necessary to stop the online control because the online operation is disabled, thus reducing the productivity.

In addition, it is necessary to clear the online-operation inhibited state after the manual operation by the operator is finished. If the online-operation inhibited state is not erroneously cleared, the online control can be stopped for a long time to also cause a reduction in productivity.

### SUMMARY OF THE INVENTION

The present invention provides, for example, an exposure apparatus capable of an online operation so as not to cause a problem in the exposure apparatus, even if an operator manually operates the exposure apparatus.

According to an embodiment of the present invention, an exposure apparatus includes a communication device configured to communicate with a host computer; an input-output device for an operator to execute a manual operation of the apparatus; a storage device; and a processor. The apparatus exposes a substrate to radiant energy in accordance with an on-line operation from the host computer and an operator operation from the input-output device. The storage device is configured to store first information indicating a manual operation that can be executed by each operator and second information indicating an online operation of which execution concurrent with each manual operation is inhibited. The processor is configured to authenticate an operator and permit execution of an online operation from the host computer based on the first information and the second information stored in the storage device and information of the authenticated operator.

According to another embodiment of the present invention, a method of manufacturing a device includes exposing a substrate to radiant energy using an exposure apparatus; developing the exposed substrate; and processing the developed substrate to manufacture the device. The exposure apparatus includes a communication device configured to communicate with a host computer; an input-output device for an operator to execute a manual operation of the apparatus; a storage device; and a processor. The apparatus exposes a substrate to radiant energy in accordance with an on-line operation from the host computer and an operator operation from the input-output device. The storage device is configured to store first information indicating a manual operation that can be executed by each operator and second information indicating an online operation of which execution concurrent with each manual operation is inhibited. The processor is configured to authenticate an operator and permit execution of an online operation from the host computer based on the first information and the second information stored in the storage device and information of the authenticated operator.

According to the present invention, it is possible to provide an exposure apparatus capable of an online operation so as not to cause a problem in the exposure apparatus, for example, even if an operator manually operates the exposure apparatus.

Further features of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a block diagram showing an example of the configuration of a system including an exposure apparatus according to an exemplary embodiment of the present invention and a host computer.

FIG. 2 illustrates examples of operator operation settings.

FIG. 3 illustrates examples of online operation settings.

FIG. 4 is a flowchart showing an example of a first process.

FIG. 5 is a flowchart showing an example of a second process.

FIG. 6 is a flowchart showing an example of a third process.

FIG. 7 is a flowchart showing an example of a fourth process.

FIG. 8 is a flowchart showing an example of a fifth process.

FIG. 9 is a flowchart showing an example of a sixth process.

### DESCRIPTION OF THE EMBODIMENTS

Exemplary embodiments of the present invention will herein be described with reference to the attached drawings.

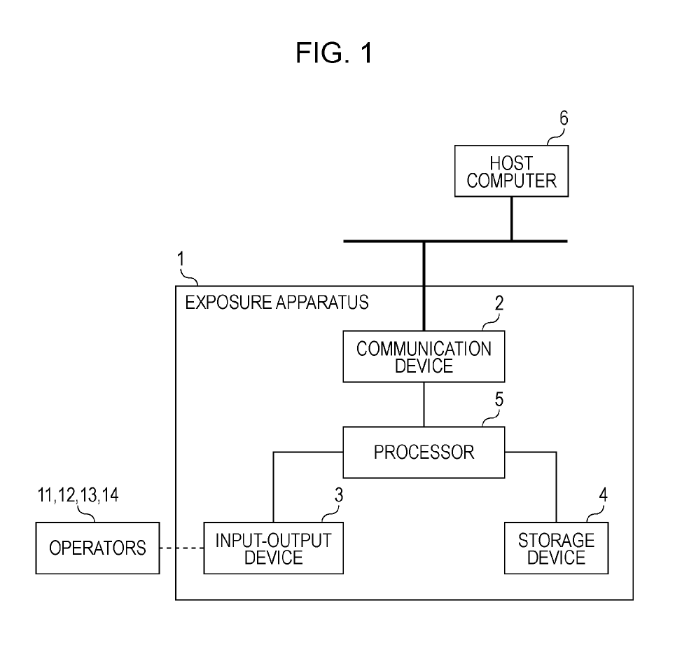

FIG. 1 is a block diagram showing an example of the configuration of a system in which an exposure apparatus 1 according to an exemplary embodiment of the present invention is online connected to a host computer 6.

The exposure apparatus 1 includes a communication device 2 communicating with the host computer 6, an input-output device 3 used for a manual operation by an operator, a storage device 4, and a processor 5. A given substrate (not shown) is exposed to radiant energy by the exposure apparatus 1 in accordance with an online operation from the host computer 6 and an operator operation with the input-output device 3.

The communication device 2 communicates with the host computer 6 online connected to the exposure apparatus 1. The input-output device 3 is used by operators 11, 12, 13, and 14 to input or output information used for manually operating the exposure apparatus 1. The information is written and stored in the storage device 4 and is read out from the storage device 4. The processor 5 controls the communication device 2, the input-output device 3, and the storage device 4. The host computer 6 communicates with the exposure apparatus 1 to remotely execute an online operation for the exposure apparatus 1.

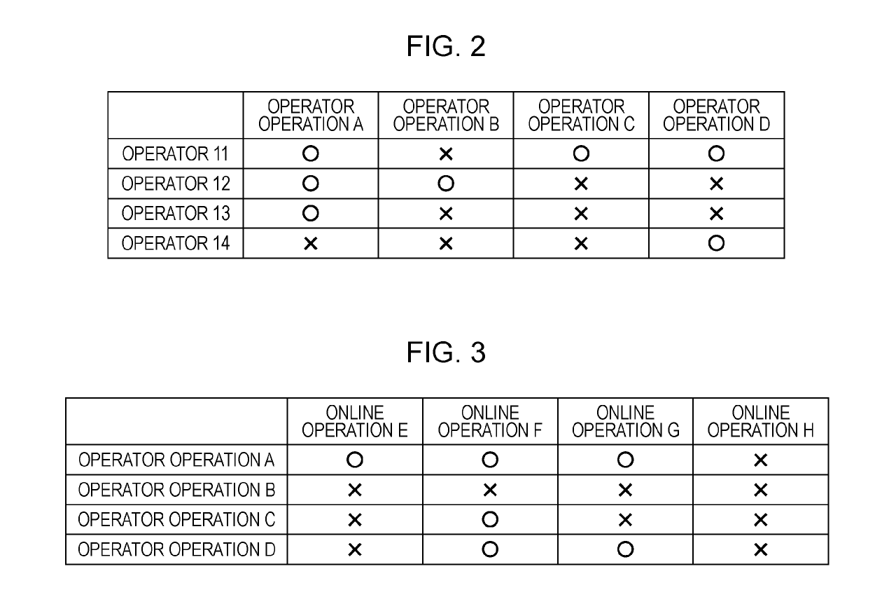

As shown in FIGS. 2 and 3, manual operations for the exposure apparatus 1, which are executed by the operators with the input-output device 3, are denoted by operator operations A, B, C, and D.

FIG. 2 illustrates examples of the settings of the operator operations A, B, C, and D which the operators 11, 12, 13, and 14 can execute.

As described above, the exposure apparatus 1 of the present exemplary embodiment includes the input-output device 3, the storage device 4, and the processor 5, which authenticate the operators.

The storage device 4 stores information about operator operation settings indicating the manual operations which each operator can execute and information about online operation settings indicating the online operations that are inhibited to be executed concurrently with each manual operation. Specifically, the settings (operator operation settings) of the operator operations A, B, C, and D which the operators 11, 12, 13, and 14 can execute are input with the input-output device 3 or input through the online operations from the host computer 6 and are stored in the storage device 4. The online operations that can be executed from the host computer 6 are denoted by online operations E, F, G, and H in the example shown in FIG. 3. The settings (online operation settings) of the online operations E, F, G, and H that can cause problems in association with the operator operation A, B, C, and D are input with the input-output device 3 or input through the online operations from the host computer 6 and are stored in the storage device 4. If any of the online operations E, F, G, and H is instructed in an online-operation inhibited state in which execution of the online operations E, F, G, and H are inhibited, the operator operation settings and the online operation settings are read out from the storage device 4.

The processor 5 determines whether a problem can be caused on the basis of the operator operation settings and the online operation settings when the instructed online operation is executed. Specifically, the processor 5 permits execution of each online operation from the host computer 6 on the basis of the information about the operator operation settings and the information about the online operation settings, stored in the storage device 4, when the authentication is performed by the input-output device 3 and the storage device 4, which authenticate the operator.

If the processor 5 does not permit the execution of the online operation, the processor 5 transmits a signal indicating that the execution of the online operation is not permitted to the host computer 6 through the communication device 2.

In the examples in FIG. 2, the operator 11 can execute the operator operations A, C, and D for which circles (∘) are indicated but cannot execute the operator operation B for which a crisscross mark (x) is indicated.

When any of the operators 11, 12, 13, and 14 is to start the manual operation of the exposure apparatus 1, information about the operator 11, 12, 13, or 14 input with the input-output device 3 is compared with the information about the operator 11, 12, 13, or 14 stored in the storage device 4. The operator 11, 12, 13, or 14 can start the manual operation if the comparison shows that the information input with the input-output device 3 matches with the information stored in the storage device 4. For example, when the input-output device 3 is a keyboard, the identification numbers and passwords input by the operator 11, 12, 13, or 14 are compared with the information stored in the storage device 4 and, if the identification number and password input by the operator 11, 12, 13, or 14 match with the information stored in the storage device 4, the manual operation is started. When the input-output device 3 is a fingerprint reader, the fingerprint of the operator 11, 12, 13, or 14 which is read out is compared with the information stored in the storage device 4 and, if the fingerprint of the operator 11, 12, 13, or 14 matches with the information stored in the storage device 4, the manual operation is started. The method (authentication method) of comparing the information about the operator 11, 12, 13, or 14 which is input with the information stored in the storage device 4 is not restricted to the above one and any other method may be used in the present invention.

When any of the operators 11, 12, 13, and 14 starts the manual operation in the above manner, the processor 5 reads out the operator operation(s) that can be executed by the operator 11, 12, 13, or 14 who is currently operating the exposure apparatus 1 from the operator operation settings stored in the storage device 4 and causes only the manual operations that can be executed to be enabled.

The content shown in FIG. 2 is only examples, and the number and content of the operators 11, 12, 13, and 14 and the number and content of the operator operations A, B, C, and D are not restricted to the ones shown in FIG. 2. The settings of each operator group resulting from grouping of the operators 11, 12, 13, and 14 on the basis of a predetermined condition may be used, instead of the settings of each operator.

FIG. 3 illustrates examples of the settings of the online operations E, F, G, and H for each of the operator operations A, B, C, and D shown in FIG. 2.

In the examples shown in FIG. 3, while the operator operation A is being executed, execution of the online operations E, F, and G for which circles are indicated does not cause a problem while execution of the online operation H for which a crisscross is indicated can cause a problem. For example, when the operator operation A indicates a manual operation of updating the settings concerning a semiconductor manufacturing process and the online operation E indicates an online operation of acquiring the value of a variable indicating the state, such as the internal temperature or humidity, of the exposure apparatus 1, the operator operation A is not associated with the online operation E. Accordingly, if the operator operation A is executed concurrently with the online operation E, no problem can be caused. In contrast, when a semiconductor manufacturing process is started with the online operation H from the host computer 6 while an operator operation of updating the setting concerning the semiconductor manufacturing process is being executed, the semiconductor manufacturing process can possibly be performed with wrong settings to cause a problem.

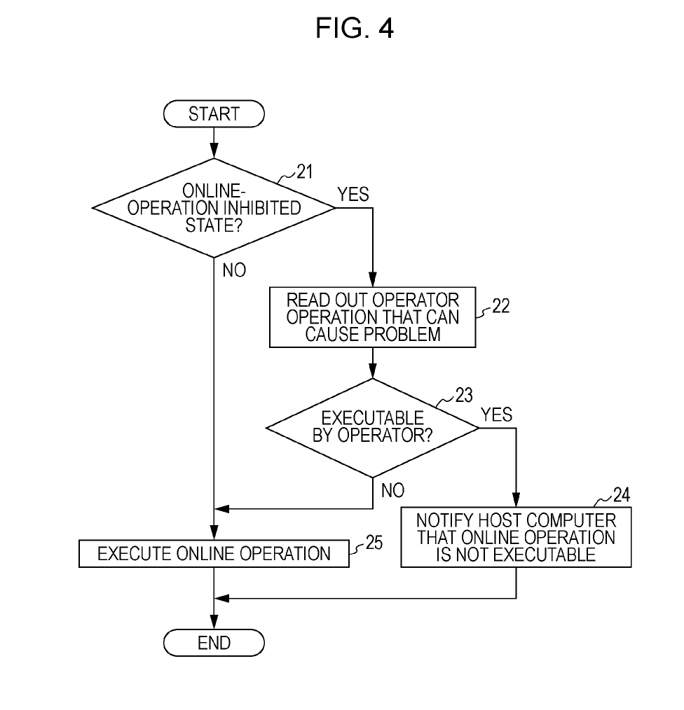

FIG. 4 is a flowchart showing an example of a process in which the processor 5 determines whether an online operation that is instructed is executable to execute the online operation or to notify the host computer 6 that the online operation is not executable. If the processor 5 does not permit the execution of the online operation, the processor 5 transmits a signal indicating the inexecutable online operation to the host computer 6 through the communication device 2.

Referring to FIG. 4, in Step 21, the processor 5 determines whether the online-operation inhibited state is set for an online operation that is instructed.

If the online-operation inhibited state is not set (NO in Step 21), then in Step 25, the processor 5 executes the online operation and the process is terminated.

If the online-operation inhibited state is set (YES in Step 21), then in Step 22, the processor 5 reads out an operator operation that can cause a problem for the instructed online operation from the online operation settings stored in the storage device 4.

In Step 23, the processor 5 determines whether the operator operation is included in the operator operations that can be executable by the current operator.

If the processor 5 determines that the operator operation is not included in the operator operations that can be executable by the current operator (NO in Step 23), then in Step 25, the processor 5 executes the online operation.

If the processor 5 determines that the operator operation is included in the operator operations that can be executable by the current operator (YES in Step 23), then in Step S24, the processor 5 notifies the host computer 6 of information indicating that the online operation is not executable, without executing the online operation.

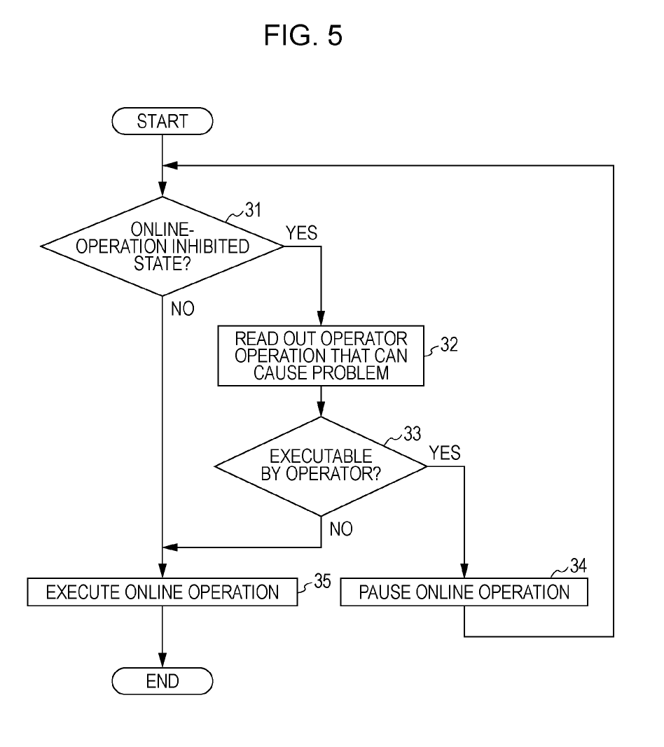

FIG. 5 is a flowchart showing an example of a process in which the processor 5 determines whether an online operation that is instructed is executable to execute the online operation or to pause the online operation. In the process, if a condition for the execution of the online operation is satisfied when the online-operation inhibited state is cleared or the operator operation is finished, the online operation is executed.

Referring to FIG. 5, in Step 31, the processor 5 determines whether the online-operation inhibited state is set for an online operation that is instructed.

If the online-operation inhibited state is not set (NO in Step 31), then in Step 35, the processor 5 executes the online operation and the process is terminated.

If the online-operation inhibited state is set (YES in Step 31), then in Step 32, the processor 5 reads out an operator operation that can cause a problem for the instructed online operation from the online operation settings stored in the storage device 4.

In Step 33, the processor 5 determines whether the operator operation is included in the operator operations that can be executable by the current operator.

If the processor 5 determines that the operator operation is not included in the operator operations that can be executable by the current operator (NO in Step 33), then in Step 35, the processor 5 executes the online operation.

If the processor 5 determines that the operator operation is included in the operator operations that can be executable by the current operator (YES in Step 33), then in Step S34, the processor 5 pauses the online operation for a predetermined time and the process goes back to the step of determining whether the online-operation inhibited state is set (Step 31), without executing the online operation.

The processes shown in FIGS. 4 and 5 are not concurrently performed for the same online operation. The process shown in FIG. 4 or 5 is selectively performed. Settings indicating which process is performed for each online operation may be stored in the storage device 4 and, when an online operation is instructed, the processor 5 may read out the setting to select either of the processes.

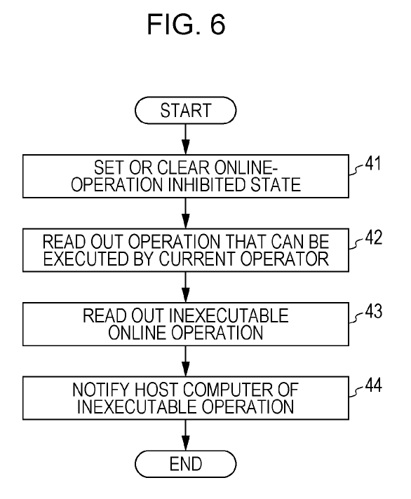

FIG. 6 is a flowchart showing an example of a process in which, when an operator sets or clears the online-operation inhibited state, the host computer 6 is notified of an online operation inexecutable for an operator operation that can be executed by the current operator.

Referring to FIG. 6, in Step 41, the operator sets or clears the online-operation inhibited state with the input-output device 3.

In Step 42, the processor 5 reads out an operator operation that can be executed by the current operator from the storage device 4 storing the operator operation settings.

In Step 43, the processor 5 reads out an online operation inexecutable for the readout operator operation from the storage device 4 storing the online operation setting.

In Step 44, the processor 5 notifies the host computer 6 of information about the inexecutable online operation. When the online-operation inhibited state is cleared, the processor 5 notifies the host computer 6 of information indicating that no inexecutable online operation exists.

As the result of the above process, the host computer 6 can recognize the online operation that is currently inexecutable. The host computer 6 does not instruct the inexecutable online operation or pauses the online operation until the online operation becomes executable.

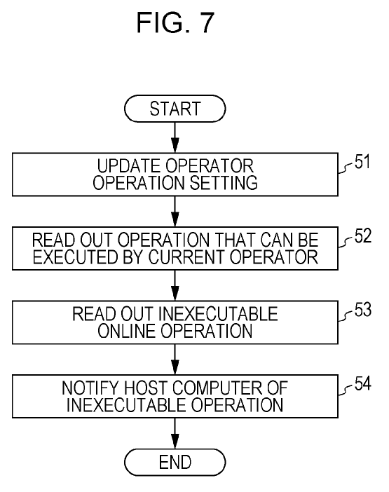

FIG. 7 is a flowchart showing an example of a process in which, when the operator operation settings are updated in the online-operation inhibited state and the updated operator operation settings are stored in the storage device 4, the host computer 6 is notified of an online operation inexecutable for an operator operation that can be executed by the current operator.

Specifically, the processor 5 transmits a signal indicating an inexecutable online operation to the host computer 6 each time the information about the operator operation settings stored in the storage device 4 are updated.

Referring to FIG. 7, in Step 51, the processor 5 updates the operator operation settings in response to an instruction input with the input-output device 3 or transmitted from the host computer 6.

In Step 52, the processor 5 reads out an operator operation that can be executed by the current operator from the storage device 4 storing the operator operation settings.

In Step 53, the processor 5 reads out an online operation inexecutable for the readout operator operation from the storage device 4 storing the online operation setting.

In Step 54, the processor 5 notifies the host computer 6 of information about the inexecutable online operation.

As the result of the above process, the host computer 6 can recognize the online operation that is currently inexecutable. The host computer 6 does not instruct the inexecutable online operation or pauses the online operation until the online operation becomes executable.

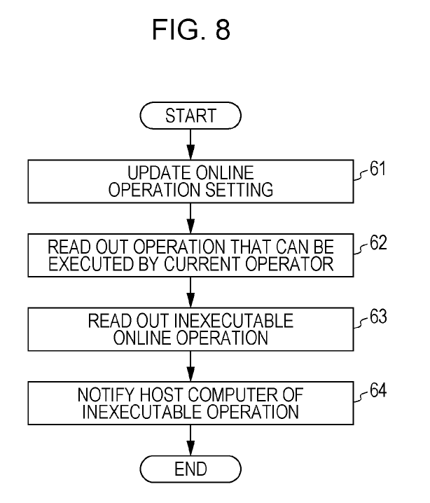

FIG. 8 is a flowchart showing an example of a process in which, when the online operation settings are updated in the online-operation inhibited state and the updated operator operation settings are stored in the storage device 4, the host computer 6 is notified of an online operation inexecutable for an operator operation that can be executed by the current operator.

Specifically, the processor 5 transmits a signal indicating an inexecutable online operation to the host computer 6 each time the information about the online operation settings stored in the storage device 4 are updated.

Referring to FIG. 8, in Step 61, the processor 5 updates the online operation settings in response to an instruction input with the input-output device 3 or transmitted from the host computer 6.

In Step 62, the processor 5 reads out an operator operation that can be executed by the current operator from the storage device 4 storing the operator operation settings.

In Step 63, the processor 5 reads out an online operation inexecutable for the readout operator operation from the storage device 4 storing the online operation setting.

In Step 64, the processor 5 notifies the host computer 6 of information about the inexecutable online operation.

As the result of the above process, the host computer 6 can recognize the online operation that is currently inexecutable. The host computer 6 does not instruct the inexecutable online operation or pauses the online operation until the online operation becomes executable.

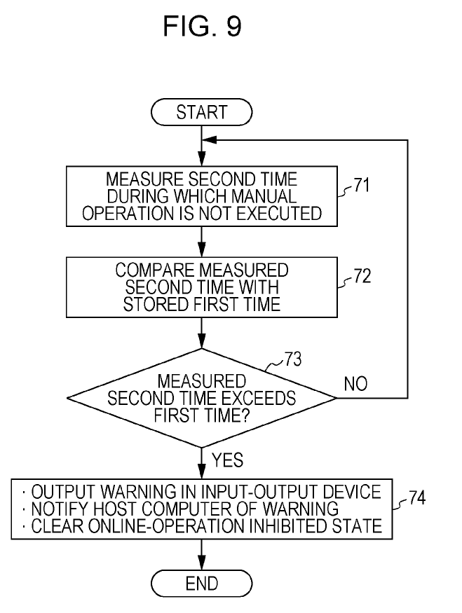

FIG. 9 is a flowchart showing an example of a process in which, when no operator operation is executed for the exposure apparatus 1 in the online-operation inhibited state for a predetermined time, a warning screen is displayed in the input-output device 3, the host computer 6 is notified of a warning, and/or the online-operation inhibited state is cleared. Specifically, after an operator is authenticated, the processor 5 measures the time during which no manual operation is continuously executed with the input-output device 3 and, if the measured time exceeds a predetermined threshold value, causes the input-output device 3 to output a signal indicating that no manual operation is continuously executed.

In addition, after an operator is authenticated, the processor 5 measures the time during which no manual operation is continuously executed with the input-output device 3 and, if the measured time exceeds a predetermined threshold value, transmits a signal indicating that no manual operation is continuously executed to the host computer 6 through the communication device 2.

Referring to FIG. 9, in Step 71, the processor 5 measures the time (second time) during which the operator executes no operator operation for the exposure apparatus 1.

In Step 72, the processor 5 compares the measured second time with a first time stored in the storage device 4.

In Step 73, the processor 5 determines whether the measured second time exceeds the stored first time. If the processor 5 determines that the measured second time does not exceed the stored first time (NO in Step 73), the process goes back to Step 71 to continue the measurement of the second time during which the operator executes no operator operation for the exposure apparatus 1.

If the processor 5 determines that the measured second time exceeds the stored first time (YES in Step 73), then in Step 74, the processor 5 selectively performs at least one of the following steps:
outputting of information indicating the warning in the input-output device 3
notification of information indicating the warning to the host computer 6
clearance of the online-operation inhibited state (authentication).

If the online-operation inhibited state is not erroneously cleared after the operator finishes the manual operation and the online control is suspended for a time exceeding the first time, the above process can be performed to reduce a time for waiting the online operation.

In addition, the online-operation inhibited state may be automatically cleared to restart the online control. Accordingly, it is possible to prevent a reduction in productivity because of the online control that is suspended for a time longer than necessary.

Specifically, the processor 5 measures the time during which no manual operation is continuously executed with the input-output device 3 after the operator is authenticated and clears the authentication if the measured time exceeds a threshold value. When the authentication is cleared, the processor 5 transmits a signal indicating that the authentication is cleared to the host computer 6 through the communication device 2.

Next, a method of manufacturing a device (semiconductor device, liquid crystal display device, etc.) according to an exemplary embodiment of the present invention is described.

The semiconductor device is manufactured through a front-end process in which an integrated circuit is formed on a wafer, and a back-end process in which an integrated circuit chip is completed as a product from the integrated circuit on the wafer formed in the front-end process. The front-end process includes a step of exposing a wafer with a photoresist coated thereon to light using the above-described exposure apparatus according to the exemplary embodiment of the present invention, and a step of developing the exposed wafer. The back-end process includes an assembly step (dicing and bonding), and a packaging step (sealing).

The liquid crystal display device is manufactured through a process in which a transparent electrode is formed. The process of forming a transparent electrode includes a step of coating a photoresist on a glass substrate with a transparent conductive film, a step of exposing the glass substrate with the photoresist coated thereon to radiant energy (light, x-ray, charged-particle beam, etc.) using the above-described exposure apparatus, and a step of developing the exposed glass substrate.

The device manufacturing method of this embodiment has an advantage, as compared with a device manufacturing method in related art, in at least one of performance, quality, productivity and production cost of a device.

While the present invention has been described with reference to exemplary embodiments, it is to be understood that the invention is not limited to the disclosed exemplary embodiments. The scope of the following claims is to be accorded the broadest interpretation so as to encompass all modifications and equivalent structures and functions.

This application claims the benefit of Japanese Patent Application No. 2008-208253 filed Aug. 12, 2008, which is hereby incorporated by reference herein in its entirety.

What is claimed is:

1. An exposure apparatus comprising:
a communication device configured to communicate with a host computer;
an input-output device for an operator to execute a manual operation of the apparatus;
a storage device; and
a processor, the apparatus exposing a substrate to radiant energy in accordance with an on-line operation from the host computer and an operator operation from the input-output device, wherein
the storage device is configured to store first information indicating a manual operation that can be executed by each operator and second information indicating an online operation of which execution concurrent with each manual operation is inhibited, and
the processor is configured to authenticate an operator and permit execution of an online operation from the host computer based on the first information and the second information stored in the storage device and information of the authenticated operator.

2. An apparatus according to claim 1,
wherein the processor is configured to transmit a signal indicating that the execution of the online operation is not permitted to the host computer via the communication device, if the processor does not permit the execution of the online operation.

3. An apparatus according to claim 1,
wherein the processor is configured to transmit a signal indicating an inexecutable online operation to the host computer via the communication device.

4. An apparatus according to claim 3,
wherein the processor is configured to transmit a signal indicating the inexecutable online operation each time the first information stored in the storage device is updated.

5. An apparatus according to claim 3,
wherein the processor is configured to transmit a signal indicating the inexecutable online operation each time the second information stored in the storage device is updated.

6. An apparatus according to claim 1,
wherein the processor is configured to measure a time during which no manual operation is continuously executed with the input-output device after the authentication, and cause the input-output device, if the measured time exceeds a threshold, to output a signal indicating the exceeding.

7. An apparatus according to claim 1,
wherein the processor is configured to measure a time during which no manual operation is continuously executed with the input-output device after the authentication, and transmit, if the measured time exceeds a threshold, a signal indicating the exceeding to the host computer via the communication device.

8. An apparatus according to claim 1,
wherein the processor is configured to measure a time during which no manual operation is continuously executed with the input-output device after the authentication, and clear the authentication if the measured time exceeds a threshold.

9. An apparatus according to claim 8,
wherein the processor is configured to transmit a signal indicating that the authentication is cleared to the host computer via the communication device, if the authentication is cleared.

10. A method of manufacturing a device, the method comprising:
exposing a substrate to radiant energy using an exposure apparatus;
developing the exposed substrate; and
processing the developed substrate to manufacture the device,
wherein the exposure apparatus includes
a communication device configured to communicate with a host computer;
an input-output device for an operator to execute a manual operation of the apparatus;
a storage device; and
a processor, the apparatus exposing a substrate to radiant energy in accordance with an on-line operation from the host computer and an operator operation from the input-output device, wherein
the storage device is configured to store first information indicating a manual operation that can be executed by each operator and second information indicating an online operation of which execution concurrent with each manual operation is inhibited, and
the processor is configured to authenticate an operator and permit execution of an online operation from the host computer based on the first information and the second information stored in the storage device and information of the authenticated operator.
